(19) United States
(12) Patent Application Publication
(10) Pub. No.: US 2013/0279268 A1
(43) Pub. Date: Oct. 24, 2013

(54) EEPROM CELL WITH STORAGE CAPACITOR

(71) Applicant: ELECTRONICS AND TELECOMMUNICATIONS RESEARCH, Daejeon (KR)

(72) Inventor: Jin-Yeong KANG, Daejeon (KR)

(73) Assignee: Electronics and Telecommunications Research Institute, Daejeon (KR)

(21) Appl. No.: 13/653,711

(22) Filed: Oct. 17, 2012

(30) Foreign Application Priority Data
Apr. 24, 2012 (KR) 10-2012-0042874

(51) Int. Cl. G11C 16/10

(52) U.S. Cl. 365/185.29; 365/185.18

(57) ABSTRACT

In an EEPROM cell, as a storage capacitor is added between a control plate and a tunneling plate, after the storage capacitor is charged for a time that is relatively smaller than a time necessary for writing or erasing data of the EEPROM cell, the EEPROM cell that can perform operation of writing or erasing data of the EEPROM cell using a charge voltage that is stored at the storage capacitor is provided. Therefore, operation of writing or erasing data of the EEPROM cell within a short time using the EEPROM cell can be performed, and thus entire productivity of the EEPROM can be improved.

### CROSS-REFERENCE TO RELATED APPLICATION

This application claims priority to and the benefit of Korean Patent Application No. 10-2012-0042874 filed in the Korean Intellectual Property Office on Apr. 24, 2012, the entire contents of which are incorporated herein by reference.

### BACKGROUND OF THE INVENTION

(a) Field of the Invention

The present invention relates to an EEPROM cell. More particularly, the present invention relates to an EEPROM cell that has a storage capacitor therein to thus quickly charge the storage capacitor and that performs a writing or erasing operation of the EEPROM cell using a charge voltage that is stored at the storage capacitor.

(b) Description of the Related Art

An electrically erasable programmable read-only memory (EPROM) is a kind of a programmable read only memory (PROM), and is a ROM that improves a drawback of an erasable programmable read only memory (EPROM) that can erase contents when ultraviolet rays are radiated thereto. By applying an electrical signal to one pin of a chip, the EPROM can erase internal data.

Such an EEPROM is a non-volatile memory element and is currently being used for a system-on-chip (SoC) or a radio frequency identification (RFID) tag. In this case, the EEPROM has various capacities from several tens of bytes to several gigabytes according to use of a product, and particularly, when the EEPROM is used for an RFID, the EEPROM should have good adhesion and thus an increase in density and a super-decrease in size of a chip is requested along with good economic efficiency.

When a product of a SoC chip or an RFID tag using an EEPROM is available, chip identification (ID) is written, the writing time of the chip ID has a great influence on productivity of a chip.

In an EEPROM, the writing time of chip ID is generally about several ms, and in order to reduce the size of the EEPROM, when the operation voltage is lowered, the writing time of the chip ID increases inversely proportionally to the lowered operation voltage. As a solution to the problem, a method of using a ferroelectric random access memory (FRAM) as a non-volatile memory or a method of increasing an operation voltage of an EEPROM is used.

However, the method of using the FRAM cannot be compatible with an existing semiconductor process, a noxious material may be used, and when performing a writing or erasing operation, tolerance to mutual disturbance between adjacent cells is weak. In order to prevent this, a circuit and a complicated procedure are added. When an operation voltage of an EEPROM is increased, there is a drawback that the chip price may increase and fine processing cannot be performed.

### SUMMARY OF THE INVENTION

The present invention has been made in an effort to provide an EEPROM cell and a method of writing or erasing data thereof having advantages of shortening a time necessary for writing or erasing data of an EEPROM without increasing an operation voltage of the EEPROM cell.

An exemplary embodiment of the present invention provides an EEPROM cell that can shorten a time necessary for writing or erasing data. The EEPROM cell include: a tunneling plate; a control plate; a floating plate that receives a voltage from the control plate; a tunneling region that is formed between the floating plate and the tunneling plate; and a storage capacitor that connects the floating plate and the tunneling plate, wherein one side plate of the storage capacitor is connected to the control plate, the other side plate thereof is connected to the tunneling plate, the one side plate and the other side plate are charged by a difference between voltages that are applied to the control plate and the tunneling plate, and even if voltages that are applied to the control plate and the tunneling plate is intercepted, a voltage when the voltage is applied is stored.

The EEPROM cell may further include: a first switch that connects the control plate and a word line; a second switch that connects the tunneling plate and a bit line; and a storage selection line that operates the first switch and the second switch.

In the EEPROM cell, the first switch or the second switch may be a metal oxide semiconductor field effect transistor (MOSFET), and gates of the MOSFET may be connected to form the storage selection line.

In the EEPROM cell, as a capacity of the storage capacitor increases, a time necessary for writing or erasing data of the EEPROM cell may be shortened.

In the EEPROM cell, the storage capacitor may be a high integrated metal-insulator-metal capacitor.

Another embodiment of the present invention provides a method of writing or erasing data of an EEPROM cell that performs operation of writing or erasing data by storing charges at a floating gate by a voltage difference between a control gate and a drain. The method includes charging, when voltages of different magnitudes are applied to the control gate and the drain, a storage capacitor having one side plate that is connected to the control gate and having the other side plate that is connected to the drain, and storing charges at the floating gate by transferring a voltage difference between the control gate and the drain using a charge voltage that is stored at the storage capacitor.

The method may further include intercepting the voltages that are applied to the control gate and the drain after the charging of a storage capacitor.

A charging time of the storage capacitor may be 10 ns-100 ns.

### BRIEF DESCRIPTION OF THE DRAWINGS

FIG. 1 is a diagram illustrating an EEPROM cell according to an exemplary embodiment of the present invention.

FIG. 2 is a circuit diagram of an EEPROM cell in which a time necessary for writing and erasing is shortened according to an exemplary embodiment of the present invention.

FIG. 3 is a cross-sectional view of an EEPROM cell in which a time necessary for writing and erasing is shortened according to an exemplary embodiment of the present invention.

FIG. 4 is a diagram illustrating an array of an EEPROM cell in which a time necessary for writing and erasing is shortened according to an exemplary embodiment of the present invention.

FIG. 5 is a diagram illustrating a sensing operation of an EEPROM cell in which a time necessary for writing and erasing is shortened according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In addition, in the entire specification and claims, unless explicitly described to the contrary, the word “comprise” and variations such as “comprises” or “comprising” will be understood to imply the inclusion of stated elements but not the exclusion of any other elements.

Hereinafter, an EEPROM cell and writing, erasing, standby, and sensing operations of the EEPROM cell according to an exemplary embodiment of the present invention will be described in detail with reference to the drawings.

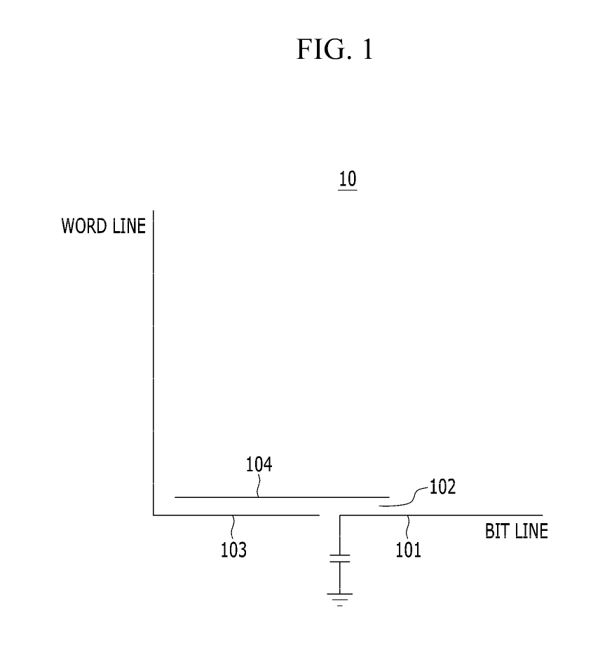

FIG. 1 is a diagram illustrating an EEPROM cell according to an exemplary embodiment of the present invention.

Referring to FIG. 1, an EEPROM cell 10 includes a tunneling plate 101, a tunneling region 102, a control plate 103, and a floating plate 104.

When a voltage is applied to a word line, it is transferred to the control plate 103 that is connected to the word line, and due to a relatively wide capacitor area that is formed by the control plate 103 and the floating plate 104, the voltage of the control plate 103 is transferred to the floating plate 104. Thereafter, a voltage difference occurs between the floating plate 104 and the tunneling plate 101 that is connected to a bit line and to which a voltage that is applied to the bit line is transferred, and thus, due to a voltage difference between the word line and the bit line, an electric field is formed in the tunneling region 102.

By charging and discharging charges to and from the floating plate 104 according to an electric field that is formed in the tunneling region 102, the EEPROM cell 10 performs operations of writing and erasing data.

In such an EEPROM cell 10, when a time in which a voltage is applied to a word line and a bit line is appropriately secured, charges can be fully charged to the floating plate 104. However, as the time necessary for operation of writing and erasing data of the EEPROM cell 10 is reduced, productivity increases, and thus a method of reducing the time necessary for writing and erasing data of the EEPROM cell 10 is requested.

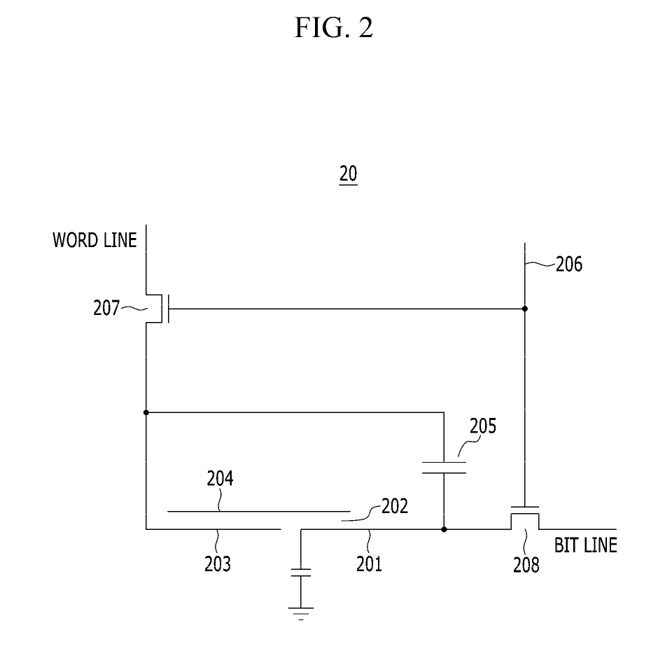

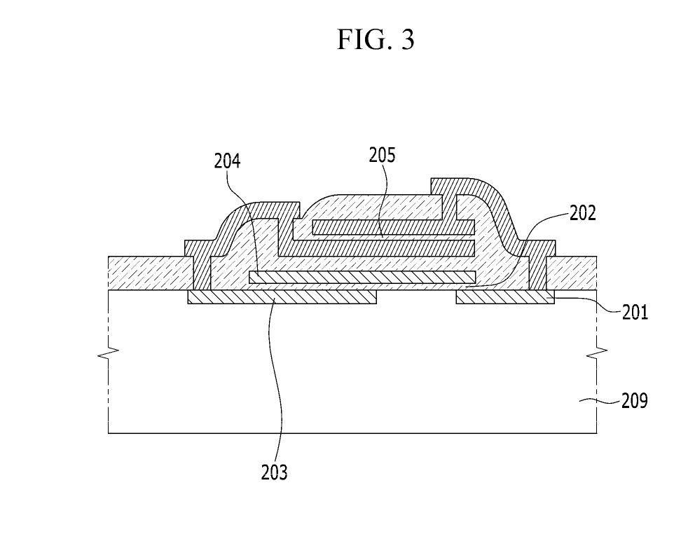

FIGS. 2 and 3 are diagrams of an EEPROM cell in which a time necessary for writing and erasing is shortened according to an exemplary embodiment of the present invention. FIG. 2 is a circuit diagram of an EEPROM cell in which a time necessary for writing and erasing is shortened, and FIG. 3 is a cross-sectional view of an EEPROM cell in which a time necessary for writing and erasing is shortened.

Referring to FIGS. 2 and 3, an EEPROM cell (hereinafter referred to as an ‘improved EEPROM cell’) 20 in which a time necessary for writing and erasing is shortened includes a tunneling plate 201, a tunneling region 202, a control plate 203, a floating plate 204, a storage capacitor 205, a storage signal line 206, switches 207 and 208, and a p-type substrate 209.

The control plate 203 and the tunneling plate 201 are formed on the p-type substrate 209, and a tunneling region 202 is formed between the floating plate 204 and the tunneling plate 201 that are formed thereon. The p-type substrate 209 is connected to ground, and a capacitor that is formed by a thickness of the p-type substrate 209 is formed to be included between the tunneling capacitor 201 and the ground, as shown in FIG. 2.

As one side plate of the storage capacitor 205 is connected to the control plate 203 and the other side plate thereof is connected to the tunneling plate 201, when voltages are applied to a word line and a bit line, a voltage difference between both sides is stored, and even if voltages that are applied to the word line and the bit line are intercepted, the voltage difference between the control plate 203 and the tunneling plate 201 may be maintained for a predetermined time period.

In more detail, as a voltage is applied to the storage signal line 206, when the switches 207 and 208 operate, voltages that are applied to the word line and the bit line are transferred to the control plate 203 and the tunneling plate 201, respectively. In this case, as shown in FIG. 2, a metal oxide semiconductor field effect transistor (MOSFET) may be used as the switches 207 and 208, but any element that is included within an EEPROM cell to perform a function of selecting an EEPROM cell to perform the operation of writing or erasing data may be used as a switch of the improved EEPROM cell 20.

Thereafter, operation of writing or erasing data is performed by an electric field of the tunneling region 202 that is formed according to a magnitude of voltages that are applied to the word line and the bit line, and the storage capacitor 205 is simultaneously charged. In this case, the operation of writing or erasing data of the improved EEPROM cell 20 requires a time period of several ms, but charge of the storage capacitor 205 requires a time period of several tens of ns, and thus charge of the storage capacitor 205 is completed and then a writing or erasing operation of the improved EEPROM cell is performed.

That is, according to an exemplary embodiment of the present invention, even if operation of writing or erasing data of the improved EEPROM cell 20 is not complete, when only the charge of the storage capacitor 205 is complete, even when voltages that are applied to the word line and the bit line are intercepted, the operation of writing or erasing data of the improved EEPROM cell 20 can be continued using a voltage difference that is stored at the storage capacitor 205, and thus when the charge of the storage capacitor 205 is complete, a voltage that is applied to the storage signal line 206 is intercepted, and operation of writing or erasing data of another EEPROM cell is performed.

As described above, while the storage capacitor 205 maintains a voltage difference between the control plate 203 and the tunneling plate 201, even if there is no voltage applied to the word line and the bit line, the improved EEPROM cell 20 can perform the operation of writing or erasing data, and while a time necessary for operation of writing or erasing data of each EEPROM cell is shortened to a time that charges the storage capacitor 205, productivity of all EEPROM cells can increase.

In this case, a time necessary for the writing and erasing operations of the EEPROM cell is determined according to several indexes such as a production purpose or improvement of productivity of the EEPROM cell, and by adjusting a sustaining time of a voltage difference by changing the capacity of the storage capacitor 205, a time necessary for operation of the writing or erasing data of the improved EEPROM cell 20 is determined.

According to an exemplary embodiment of the present invention, the size of the storage capacitor 205 may be about ⅕-⅓ of the size of an entire capacitor in which the floating plate 204 is formed. In this case, as the capacity of the storage capacitor 205 increases, the time necessary for operation of the writing and erasing data of the improved EEPROM cell 20 can be shortened. This is because, when the storage capacitor 205 has a large capacity, when the same voltage difference is transferred, the storage capacitor 205 can store more charges, and after voltages that are applied to the word line and the bit line are intercepted, charges that are stored at the storage capacitor 205 form an electric field, and thus a voltage difference may be formed in both plates of the storage capacitor 205.

For example, when the entire capacitance of an EEPROM cell in which the floating plate 204 is formed is 0.001 pF-0.01 pF, if the capacity of the storage capacitor 205 becomes 32% of the entire capacitance, the time necessary for writing and erasing operations of the improved EEPROM cell 20 may be within 10 seconds, and if the capacity of the storage capacitor 205 becomes 19% of entire capacitance, the time necessary for a writing and erasing operation of the improved EEPROM cell 20 may be within 30 days.

Further, when a capacity of the storage capacitor 205 decreases to 25%, 23%, and 21% of the entire capacitance, the time necessary for writing and erasing operations of the EEPROM cell may increase to within 10 minutes, within 1 hour, and within 1 day, respectively.

As the storage capacitor 205, a high integrated metal-insulator-metal (MIM) capacitor may be used.

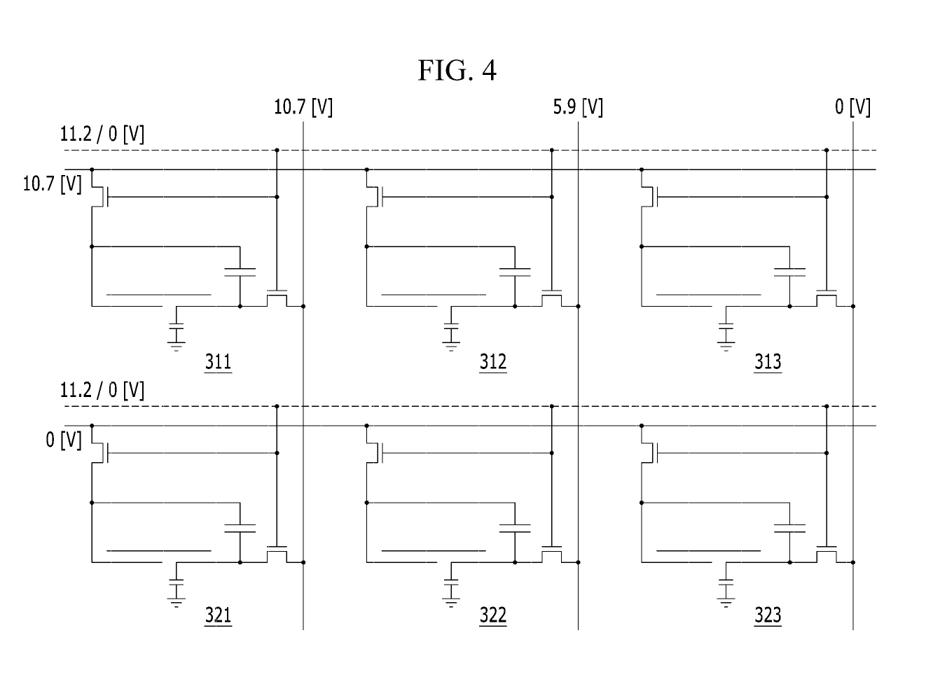

FIG. 4 is a diagram illustrating an array of an EEPROM cell in which a time necessary for writing and erasing is shortened according to an exemplary embodiment of the present invention.

Referring to FIG. 4, according to an exemplary embodiment of the present invention, a voltage of 0 V, 5.9 V, or 10.7 V may be applied to a bit line, and 0 V or 10.7 V may be applied to a word line. In this case, if 5.9 V is applied to the word line, when tunneling characteristics of the word line are a writing or erasing operation, the word line has asymmetric characteristics and thus disturbance occurs in a non-selection cell that is connected to a line to which 5.9 V is applied to the word line and thus data that are stored at the EEPROM cell may be lost, whereby 5.9 V is not applied to the word line.

Further, a voltage of 0 V or 11.2 V may be applied to the storage selection line. In this case, the reason why a voltage to be applied to the storage selection line is 11.2 V is that, in order to transfer a voltage of 10.7 V to be input to the word line or the bit line without attenuation, a threshold voltage of 0.5 V of the MOSFET is added to 10.7 V. Hereinafter, writing and erasing operations of the improved EEPROM cell will be described with reference to FIG. 4 and Table 1.

The operation of the improved EEPROM cell 20 is generally performed in order of ‘standby->preliminary erasing->erasing->standby->preliminary writing->writing->standby’.

First, in FIG. 4, when 11.2 V is applied to the storage selection line, an EEPROM cell 313 in which 10.7 V is applied to the word line and in which 0 V is applied to the bit line is a cell to perform a preliminary writing operation. As 11.2 V is applied to the storage selection line, when the charge of the storage capacitor of the EEPROM cell 313 is started, as several tens of ns has elapsed, the charge is complete, and then when 0 V is applied to the storage selection line, the EEPROM cell 313 performs a writing operation by only a charge voltage that is stored at the storage capacitor regardless of voltages of the word line and the bit line.

TABLE 1
Operation condition of improved EPROM cell

| | | Operation [V] | | | | |
|---|---|---|---|---|---|---|
| | | | Prelim- | | Prelim- | |
| | | | inary | | inary | |
| | Line | Standby | erasing | Erasing | writing | Writing |
| Selected | Word line | 0-10.7 | 0 | 0-10.7 | 10.7 | 0-10.7 |
| cell | Bit line | 5.9 | 10.7 | 0-10.7 | 0 | 0-10.7 |
| | Storage | 11.2 | 11.2 | 0 | 11.2 | 0 |
| | selection | | | | | |
| | line | | | | | |
| Non- | Word line | 0-10.7 | 0-10.7 | 0-10.7 | 0-10.7 | 0-10.7 |
| selected | Bit line | 5.9 | 10.7 | 0-10.7 | 0 | 0-10.7 |
| cell | Storage | 0 | 0 | 0 | 0 | 0 |
| | selection | | | | | |
| | line | | | | | |

In FIG. 4, when 11.2 V is applied to the storage selection line, an EEPROM cell 321 in which 0 V is applied to the word line and in which 10.7 V is applied to the bit line is a cell to perform a preliminary erasing operation. As 11.2 V is applied to the storage selection line, the charge of the storage capacitor of the EEPROM cell 321 is started, when a time period of several tens of ns has elapsed, the charge is complete, and then when 0 V is applied to the storage selection line, the EEPROM cell 321 performs an erasing operation with only a charge voltage that is stored at the storage capacitor regardless of voltages of the word line and the bit line.

As described above, in the improved EEPROM cell 20, in a preliminary writing or preliminary erasing operation, the storage capacitor 205 of the improved EEPROM cell 20 is charged, and then in a writing or erasing operation, even if a voltage is not transferred from the word line and the bit line, a writing or erasing operation may be performed using a charge voltage that is stored at the storage capacitor 205.

That is, in order to perform the operation of writing or erasing data of the EEPROM cell, because only a time necessary for charging the storage capacitor is requested, only a time period of several tens of ns per EEPROM cell has elapsed, and then completion of an actual writing or erasing operation using a charge voltage that is stored at the storage capacitor can be adjusted by a capacity of the storage capacitor, as described above. For example, when wishing to complete the operation of writing or erasing data of an EEPROM cell within 1 day in consideration of a selling time of an RFID tag product in which an improved EEPROM cell is included, by adjusting a capacity of the storage capacitor to about 21% of the entire capacitance of the EEPROM cell, the operation of writing or erasing data may be complete.

A writing or erasing operation is most greatly influenced by a ratio of the capacitance and may be thus limited by a ratio of the capacitance, and may be limited by a natural discharge time by a p-n junction leakage current between a tunneling plate layer, which is an n-type semiconductor and a substrate, which is a p-type semiconductor. In this case, by performing a reset operation that applies 0 V to the word line and the bit line and that applies 2 V to a storage selection line, a writing or erasing operation may be randomly (compulsively) stopped.

In FIG. 4, EEPROM cells 312 and 322 in which 5.9 V is applied to a bit line are cells that perform a standby operation regardless of a voltage that is applied to a storage selection line or a word line, and in this case, a duration time is about 5×10̂-2 year (18.25 days).

EEPROM cells 311 and 323 in which 10.7 V or 0 V is equally applied to the word line and the bit line are cells in which a storage or erasing operation is not performed regardless of a voltage that is applied to a storage selection line, and in this case, the duration time is 100 years or more.

According to an exemplary embodiment of the present invention, an EEPROM cell that is embodied as a floating gate transistor of a form in which an existing floating gate is inserted is formed with plates including capacitors, and in this case, a floating plate performs a function of a floating gate, and a tunneling plate performs a function of a drain of a MOSFET. That is, even in an EEPROM cell that performs a writing or erasing operation with a method of storing charges to a floating gate by a voltage that is applied between a control gate and a drain, one side plate of a capacitor is connected to a control gate and the other side plate thereof is connected to a drain, and thus, as described in an exemplary embodiment of the present invention, by mounting a capacitor in an EEPROM cell, a necessary time for operation of writing or erasing data of the EEPROM cell can be shortened.

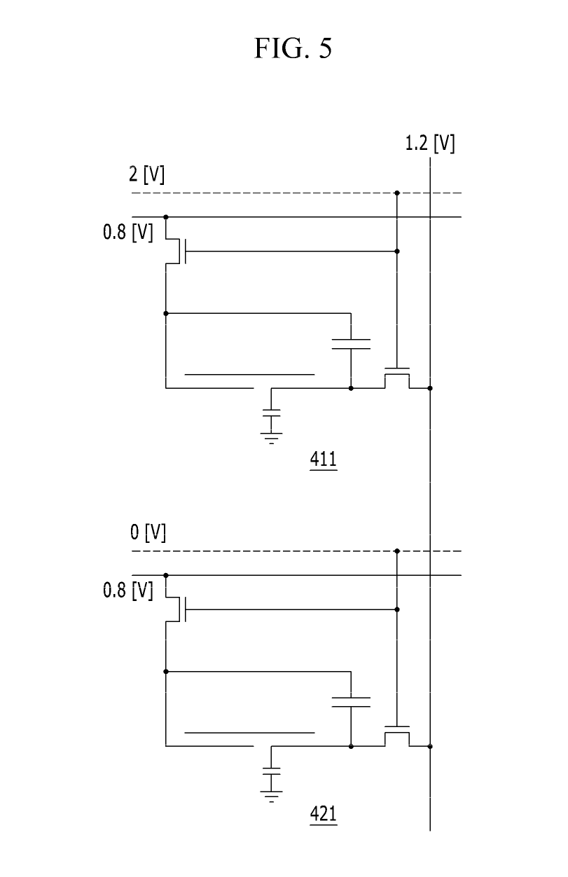

FIG. 5 is a diagram illustrating a sensing operation of an EEPROM cell in which a time necessary for writing and erasing is shortened according to an exemplary embodiment of the present invention.

When the improved EEPROM cell 20 performs a sensing operation, 0.8 V is applied to all word lines, and 1.2 V is applied to all bit lines. By applying 2 V to a storage selection line, a cell to sense is selected. Referring to FIG. 5, an improved EEPROM cell 411 in which 2 V is applied to the storage selection line is a cell that performs a sensing operation.

That is, an improved EEPROM cell 421 in which 0 V is applied to the storage selection line is not sensed, and although not shown in FIG. 5, all improved EEPROM cells in which 0 V is applied to the storage selection line do not perform a sensing operation.

When 2 V is applied to the storage selection line, a switch of the improved EEPROM cell 411 operates, and a sensing operation is performed by a current of a bit line according to charges that are stored at a floating plate. In this case, when a sensing operation is performed, capacitance between the tunneling plate and the p-type substrate disappears and the tunneling plate is directly connected to ground, and thus a sensing operation may be performed by a current flowing through a bit line according to a potential change in a floating plate that is generated by a writing or erasing operation.

According to an exemplary embodiment of the present invention, in an EEPROM cell in which data are written, many negative charges exist in a floating plate of the EEPROM cell and thus a current does not flow or weakly flows to a bit line, however, in an erased EEPROM cell in which data are not written, in a floating plate of the EEPROM cell, a negative charge hardly remains or many positive charges exist and thus a relatively large current flows to a bit line, whereby a sensing operation can be performed.

According to an exemplary embodiment of the present invention, an area of the improved EEPROM cell 20 increases due to the storage capacitor 205, and thus the improved EEPROM cell 20 can be appropriate for an EEPROM having a capacity within several Kbits, like an RFID tag.

In this way, according to an exemplary embodiment of the present invention, as a storage capacitor is added between a control plate and a tunneling plate, after the storage capacitor is charged for a relatively smaller time than a time necessary for writing or erasing data of an EEPROM cell, operation of writing or erasing data of the EEPROM cell can be performed using a charge voltage that is stored at the storage capacitor and thus the operation for writing or erasing data of the EEPROM cell can be performed within a short time, whereby the overall productivity of the EEPROM can be improved from several ms per cell to several us per cell.

According to an exemplary embodiment of the present invention, as a storage capacitor is added between a control plate and a tunneling plate, after a storage capacitor is charged for a time that is relatively smaller than a time necessary for writing or erasing data of an EEPROM cell, operation of writing or erasing data of the EEPROM cell can be performed using a charge voltage that is stored at the storage capacitor, and thus operation of writing or erasing data of the EEPROM cell can be performed within a short time and thus productivity of an EEPROM can be improved.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An EEPROM cell, comprising:
a tunneling plate;
a control plate;
a floating plate that receives a voltage from the control plate;
a tunneling region that is formed between the floating plate and the tunneling plate; and
a storage capacitor that connects the floating plate and the tunneling plate,
wherein one side plate of the storage capacitor is connected to the control plate, the other side plate thereof is connected to the tunneling plate, the one side plate and the other side plate are charged by a difference between voltages that are applied to the control plate and the tunneling plate, and even if voltages that are applied to the control plate and the tunneling plate is intercepted, a voltage when the voltage is applied is stored.

2. The EEPROM cell of claim 1, further comprising:
a first switch that connects the control plate and a word line;
a second switch that connects the tunneling plate and a bit line; and
a storage selection line that operates the first switch and the second switch.

3. The EEPROM cell of claim 2, wherein the first switch or the second switch is a metal oxide semiconductor field effect transistor (MOSFET), and
gates of the MOSFET are connected to form the storage selection line.

4. The EEPROM cell of claim 1, wherein as a capacity of the storage capacitor increases, a time necessary for writing or erasing data of the EEPROM cell is shortened.

5. The EEPROM cell of claim 1, wherein the storage capacitor is a high integrated metal-insulator-metal capacitor.

6. A method of writing or erasing data of an EEPROM cell that performs operation of writing or erasing data by storing charges at a floating gate by a voltage difference between a control gate and a drain, the method comprising:
charging, when voltages of different magnitudes are applied to the control gate and the drain, a storage capacitor having one side plate that is connected to the control gate and having the other side plate that is connected to the drain; and
storing charges at the floating gate by transferring a voltage difference between the control gate and the drain using a charge voltage that is stored at the storage capacitor.

7. The method of claim 6, further comprising intercepting the voltages that are applied to the control gate and the drain after the charging of a storage capacitor.

8. The method of claim 6, wherein a charging time of the storage capacitor is 10 ns-100 ns.
